(19) United States
(12) Patent Application Publication
(10) Pub. No.: US 2023/0059529 A1
(43) Pub. Date: Feb. 23, 2023

(54) Characterization of Rechargeable Batteries Using Machine-Learned Algorithms

(71) Applicant: TWAICE Technologies GmbH, Munchen (DE)

(72) Inventor: Michael Baumann, Munchen (DE)

(21) Appl. No.: 17/792,483

(22) PCT Filed: Jan. 14, 2021
(86) PCT No.: PCT/DE2021/100042

§ 371 Date: Jul. 13, 2022

(30) Foreign Application Priority Data
Jan. 14, 2020 (DE) 10 2020 100 668.3

(51) Int. Cl. G01R 31/392; G01R 31/367

(52) U.S. Cl. CPC G01R 31/392; G01R 31/367

(57) ABSTRACT

Various examples relate to techniques for carrying out a characterization of a rechargeable battery in a two-stage process. To this end, an upstream algorithm is used in order to determine one or more derived state variables of the battery. These are then used as input values for a machine-learned algorithm. An aging value of the battery is obtained therefrom.

### CROSS-REFERENCE TO RELATED APPLICATIONS

This application is the United States national phase of International Application No. PCT/DE2021/100042 filed Jan. 14, 2021, and claims priority to German Patent Application No. 10 2020 100 668.3 filed Jan. 14, 2020, the disclosures of which are hereby incorporated by reference in their entirety.

### BACKGROUND OF THE INVENTION

### Field of the Invention

Various examples of the invention relate generally to techniques for characterizing rechargeable batteries. In particular, various examples of the invention relate to techniques to determine an aging value of the rechargeable battery using at least one machine-learned (ML) algorithm.

### Description of Related Art

Rechargeable batteries, such as traction batteries in electric vehicles, have a limited service life. This means that an aging value can increase over time and/or as a function of discharge cycles. The aging value can be characterized by a so-called state of health (SOH). The SOH is typically determined in connection with the capacity and/or the impedance of battery cells of the battery.

As the battery ages, there may be limitations associated with operating a corresponding battery-powered device as a load of the rechargeable battery. Efforts are therefore being made to determine the aging value of the battery especially precisely.

For example, techniques are known for determining the total capacity of the battery as an aging value by means of a complete discharge. Another technique measures, for example, the plate corrosion or the electrolyte density of the battery. Yet another technique places sensors in the battery to measure cell resistance, for example. Relative techniques perform a partial discharge and compare the result to a cell model or reference cell. A Kalman filter can be used for this purpose, for example. Refer to, for example, Plett, Gregory L. “Extended Kalman filtering for battery management systems of LiPB-based HEV battery packs: Part 2. Modeling and identification.” Journal of power sources 134.2 (2004): 262-276.

One technique for determining the aging value uses an ML algorithm to determine the aging value based on measurement data such as voltage, which serve as input variables for the ML algorithm. It has been observed that such techniques sometimes give inaccurate results for the aging value.

### SUMMARY OF THE INVENTION

Therefore, there is a need for improved techniques to determine an aging value for a rechargeable battery, particularly using at least one ML algorithm. In particular, there is a need for techniques that make it possible to determine the aging value especially accurately and reliably for a wide variety of battery types.

This object is achieved by means of the features of the independent claims. The features of the dependent claims define embodiments.

A computer-implemented method for determining an aging value of a rechargeable battery comprises obtaining measurement data for one or more state variables of the battery. The method comprises determining one or more derived state variables of the battery using an upstream algorithm. In this case, the input values of the upstream algorithm comprise the one or more state variables. The method also comprises determining the aging value using at least one ML algorithm. In this case, the input values of the at least one ML algorithm comprise the one or more derived state variables of the battery.

A computer program or a computer program product or a computer-readable storage medium comprises program code. The program code can be loaded and executed by a processor. When the program code is executed by the processor, this means that the processor executes a method for determining an aging value of a rechargeable battery. The method comprises obtaining measurement data for one or more state variables of the battery as well as determining one or more derived state variables of the battery using an upstream algorithm. In this case, the input values of the algorithm comprise the one or more state variables. The method also comprises determining the aging value using at least one ML algorithm. In this case, the input values of the at least one ML algorithm comprise the one or more derived state variables of the battery.

A device comprises a processor configured to load and execute program codes. When the processor executes the program code, this means that the processor executes a method for determining an aging value of a rechargeable battery. The method comprises obtaining measurement data for one or more state variables of the battery and determining one or more derived state variables of the battery using an upstream algorithm. In this case, the input values of the upstream algorithm comprise the one or more state variables. The method also comprises determining the aging value using at least one ML algorithm. In this case, the input values of the at least one ML algorithm comprise the one or more derived state variables of the battery.

The features presented above, as well as features that are described below, can be used not only in the corresponding explicitly presented combinations, but also in further combinations or in isolation, without departing from the protective scope of the present invention.

### BRIEF DESCRIPTION OF THE DRAWINGS

FIG. 1 schematically illustrates a system comprising multiple batteries and a server according to various examples.

FIG. 2 illustrates details of a battery according to various examples.

FIG. 3 illustrates details of a server according to various examples.

FIG. 4 is a flowchart of an exemplary method.

FIG. 5 is a flowchart of an exemplary method.

FIG. 6 illustrates the data flow for determining an aging value using multiple algorithms according to various examples.

FIG. 7 schematically illustrates measurement data that indicate the state variables of a battery in the form of a load spectrum, according to various examples.

FIG. 8 schematically illustrates measurement data that indicate the state variables of the battery in the form of an event-based representation, according to various examples.

FIG. 9 schematically illustrates a time series of measurement data according to various examples.

### DETAILED DESCRIPTION OF EMBODIMENTS

The properties, features, and advantages of this invention described above, and the manner in which they are achieved, will become clearer and more easily understood in connection with the following description of the exemplary embodiments, which are explained in more detail in connection with the drawings.

In the following, the present invention will be explained in greater detail in reference to the accompanying drawings using preferred embodiments. In the figures, the same reference numbers designate the same or similar elements. The figures are schematic representations of various embodiments of the invention. Elements depicted in the figures are not necessarily drawn to scale. Rather, the various elements shown in the figures are presented in such a way that the function and general purpose thereof can be understood by one skilled in the art. Connections and couplings between functional units and elements shown in the figures can also be implemented as an indirect connection or coupling. A connection or coupling can be wired or wireless. Functional units can be implemented as hardware, software, or a combination of hardware and software.

Techniques related to the characterization of rechargeable batteries are described below. The techniques described herein can be used in connection with a wide variety of batteries, for example in connection with lithium-ion-based batteries, such as lithium-nickel-manganese-cobalt oxide batteries or lithium-manganese oxide batteries.

The batteries described herein can be used for batteries in different application scenarios, for example for batteries used in devices such as motor vehicles or drones or portable electronic devices such as mobile phones. It would also be conceivable to use the batteries described herein in the form of stationary energy storage devices. Indoor or outdoor applications are conceivable, which differ primarily with regard to the temperature ranges. Application scenarios comprise: stationary energy storage devices in a micro-grid, energy storage devices for mobile applications, low-load energy storage devices, energy storage devices for light electric vehicles such as bicycles or scooters, energy storage devices for electric passenger cars, indoor applications, and outdoor applications.

The techniques described herein make it possible to determine an aging value of the battery in connection with the characterization of the battery. The aging value correlates with the aging of the rechargeable battery. The aging value can describe the quality of the battery (and could therefore also be referred to as the Q value). The aging value, for example, can assume greater values the further the aging of the battery has progressed. The aging value can correlate with the SOH or correspond thereto. The aging value, for example, can quantify an increase in the resistance or impedance of the battery. The aging value, for example, can quantify the decrease in the overall capacity of the battery.

According to various examples described herein, it is possible that the aging value is determined using at least one ML algorithm. An ML algorithm is characterized in that, in a learning phase, parameter values of parameters of the ML algorithm are set using suitable training. The training is automated and based on training data. In the present example, the training data can comprise reference state variables of the battery, as well as a priori knowledge (ground truth) about the respectively associated aging value. Then, as part of the training, the parameter values of the ML algorithm can be adapted in such a way that, based on the reference state variables of the training data, the ML algorithm determines an aging value that matches the associated reference aging value particularly well. This therefore means that the ML algorithm can be used to perform a dimensionality reduction that maps the one or more state variables to a corresponding aging value. Examples of ML algorithms comprise, for example: artificial neural networks (ANNs), genetic algorithms, support vector machines, etc.

ANNs, for example, can be designed as a multi-layer feedforward network, in which the neurons of the different layers do not form any loops. An example of such a multi-layer feedforward ANN is a convolutional neural network, in which convolutions of the values of the neurons are carried out with a kernel in at least some layers. Pooling layers or non-linear layers can also be provided. However, it would also be possible to use recurrent ANNs, for example to take a time series into account.

Various examples of the techniques described herein are based on the recognition that reference techniques for determining the battery aging value using an ML algorithm may have certain limitations. For example, it has been observed that a very large amount of measurement data for one or more state variables of the battery is often required as input variables for the ML algorithm in order to achieve sufficient accuracy. Otherwise, for example, differences from battery to battery—even for batteries of the nominally same type, for example due to variations caused by construction—can mean that the aging value can only be determined with a certain amount of inaccuracy. Another limitation of known techniques relates to the learning phase. In this case, it can often be necessary to use a large amount of training data in order to obtain sufficient accuracy when determining the aging value.

In order to overcome these and other limitations of the reference techniques, it may be possible, according to various examples, to use a two-stage approach in connection with the determination of the aging value. In a first stage, one or more derived state variables of the battery are determined, in which the one or more derived state variables are determined based on measurement data for one or more state variables of the battery. This determination of the one or more derived state variables can take place using an upstream algorithm, with the input values thereof comprising the one or more state variables. In a second state, the aging value is determined using at least one ML algorithm. In this case, the input values of the at least one ML algorithm include the one or more derived state variables of the battery.

The measurement data can be recorded by one or more sensors. For example, current measurement sensors, voltage measurement sensors, temperature sensors, pressure sensors, stress sensors, humidity sensors, etc. could be used. The measurement data can be obtained from a management system of the battery. The measurement data can quantify the one or more states in a time-resolved manner. Alternatively or additionally, it would be conceivable for the measurement data to be provided as a so-called load spectrum; in this case, the frequency of occurrence of values of the state variable is quantified, for example, for two or more state variables relative to each other or also in relation to an absolute reference (e.g. a time reference or a charge/discharge cycle reference). This means that the measurement data provided as a load spectrum could indicate, for example, the fraction of the operating time or the operating cycles in which certain combinations of values for multiple state variables occur during operation. In particular, the load spectrum can indicate stress factors, i.e. state variables that are especially relevant for aging. The load spectrum can therefore describe a load profile of the battery. Finally—as an alternative or in addition to an implementation of the measurement data as a time-resolved series of values and/or as a load spectrum—it would be conceivable for the measurement data to indicate the one or more state variables in an event-based manner. This means that the measurement data could indicate the one or more state variables depending on one or more predefined event criteria. For example, if at least one of the one or more state variables assumes a predefined value or range of values, then the criterion for the presence of an event could be met. In this case, the measurement data for a specific time section could indicate the corresponding at least one state variable or also one or more further state variables in a time-resolved manner around the event. However, it would also be possible for the measurement data to merely indicate the presence of a corresponding event, for example the provision of a corresponding time stamp (without resolving further details on the state variables).

It would be possible for the measurement data to be obtained for a measurement time interval. The measurement time interval can extend from the current time into the past, for example for a specific predetermined measurement time period. The measurement time interval could be determined, for example, by means of a sliding window method, i.e. continuously updated and tracked as time progresses. In this way, current measurement data can be obtained that describe the current state of the battery very well. In particular, it may be possible to characterize the batteries during ongoing field operation, for example by receiving the measurement data from a management system of the battery via a communication link.

In various examples, it would be possible for the measurement data to comprise a time series for the at least one state variable. The time series can cover the measurement time interval, for example. For example, it would be possible for the measurement data to describe the temporal development of values of the at least one state variable. For example, the temporal development of current, voltage, or temperature values could be obtained with a certain sampling rate. However, it would also be possible for the temporal dependency of load spectra to be indicated as part of the measurement data. This means that, for example, a time series of load spectra is obtained for different points in time. A change in the frequency of occurrence of values of the state variables can be described in this way. A time series can also be provided in connection with event-based measurement data. For example, the frequency of specific events could be indexed in a time-resolved manner, i.e. it is possible to specify how often a specific event occurred in a specific time interval.

It would be conceivable that the one or more state variables are selected from the following group: electrical current flow, electrical voltage, temperature, humidity, ambient pressure, stress, etc. The one or more state variables can also be referred to as directly observable state variables of the battery because they can be indicated by the measurement data, i.e. can be measured by sensors, for example.

As described above, it is then possible to determine one or more derived state variables of the battery using an upstream algorithm. This means that the one or more derived state variables can also be referred to as hidden observables because they cannot be measured directly by corresponding sensors. The upstream algorithm can be implemented as mapping that maps the one or more state variables to the one or more derived state variables.

If the measurement data comprise a time series of the at least one state variable, then it is also possible for a time series of the one or more derived state variables to be determined using the upstream algorithm. For example, the upstream algorithm could be executed repeatedly, namely once for each point in time in the time series. A time series of derived state variables is obtained in this way. However, also conceivable are upstream algorithms which directly receive the time series of one or more state variables as an input variable and use this to determine a single derived state variable, for example at the actual point in time.

It would also be possible for the upstream algorithm to provide a prediction for the one or more derived state variables. For example, it would be conceivable that the one or more state variables are obtained for one or more points in time in the measurement time interval. A prediction could then be made using the upstream algorithm, for example taking into account a historical operating profile of the battery. This prediction for the one or more derived state variables could then be given to the ML algorithm as an input so that the algorithm also determines a prediction for the aging value (based on the prediction for the one or more derived state variables).

As a general rule, different upstream algorithms can be used with the techniques described herein. (i) For example, an analytic algorithm that implements a fixed map could be used. The analytical algorithm could have parameter values that are determined, for example, empirically, for example based on laboratory measurements. (ii) A numerical algorithm could also be used, for example in the context of a simulation of the electrical and/or thermal state of the battery. For example, a finite element methodology could be used. (iii) In some examples in particular, the upstream algorithm cannot use any ML and can thus distinguish itself from the at least one downstream ML algorithm. In contrast to the ML algorithm, a learning phase for the upstream algorithm can be omitted, i.e. in particular no machine-implemented automatic training based on training data is provided for the upstream algorithm. Manual parameterization of the algorithm is possible. (iv) For example, a Kalman filter could be used to implement the upstream algorithm. The Kalman filter can comprise a cell model of battery cells. The cell model can depend on the one or more derived state variables. It is then possible to determine the one or more derived state variables using the Kalman filter by adjusting the values of the one or more derived state variables of the Kalman filter model until the value of the modeled state variable corresponds well with the value of the observed state variable. (v) The upstream algorithm could also use a simulation. For example, a load profile of the battery could be used to estimate the development of one or more derived state variables in the future—i.e. assuming that the load profile observed in the past will also be present for this battery in the future. For example, the load profile could generally describe quantities such as a discharge rate, depth of discharge, etc. The load profile can be obtained from the one or more state variables, or the load profile can be obtained directly in the form of the measurement data, for example as a load spectrum.

In general, it would be possible for more than one single upstream algorithm to be used, such as a combination of the aforementioned examples. It would thus be conceivable to determine more than one derived state variable. Various upstream algorithms can at least partially access measurement data that relate to different state variables of the battery.

In various examples, it is conceivable that at least one derived state variable of the one or more derived state variables has a correlation with a respective aging mechanism of the battery. In particular, it would be possible for a temporal development of one or more of the at least one derived state variable to have a correlation with a respective aging mechanism or a temporal development of the respective aging mechanism of the battery.

As a general rule, rechargeable batteries can be subject to a variety of aging mechanisms. Aging mechanisms can be caused by physical and/or chemical processes. Aging mechanisms can cause, for example, the loss of negative electrode material, the loss of positive electrode active material, or the loss of ions exchanged between positive and negative electrodes (i.e., the loss of lithium in the case of lithium-ion batteries). Various aging mechanisms are described, for example, in Birkl, Christoph R., et al. “Degradation diagnostics for lithium ion cells.” Journal of Power Sources 341 (2017): 373-386: FIG. 3, second column from the left. Because the one or more derived state variables correlate with the aging mechanisms, it may be possible for the at least one ML algorithm to quantify one or more aging mechanisms. If the ML algorithm quantifies multiple aging mechanisms, the aging value may be determined based on a combination of values for the multiple aging mechanisms, which values are obtained from the at least one ML algorithm as an output value.

Such one or more aging mechanisms can generally be selected from the following group: lithium deposition on electrodes of cells of the battery, formation and growth of a solid electrolyte interphase (SEI), or loss of electronic contact, for example, due to particle breakage. The deposition of lithium and the formation of corresponding dendrites is a significant aging mechanism for lithium-ion batteries.

Using the techniques described herein, it is possible, in particular, to take into account several such aging mechanisms when characterizing the battery and thereby to determine an especially precise aging value.

In some examples, a temporal development of such aging mechanisms can be taken into account. In this way, for example, a prediction can be made for the aging value of the battery which takes into account the temporal development of the one or more aging mechanisms.

For example, an ML algorithm can be used which can make a temporal prediction based on the temporal development of the one or more derived state variables. This means that the ML algorithm can receive a corresponding time series of values of the one or more derived state variables as an input. Examples comprise a recurrent artificial neural network, such as a long short-term memory (LSTM) network.

In some examples, it would be conceivable for multiple ML algorithms to be used. These can then be assigned to different aging mechanisms. This means that different ML algorithms output values that quantify different aging mechanisms. Accordingly, it is possible that the various ML algorithms obtain different derived state variables as input variables. The multiple ML algorithms can therefore be connected in parallel. Such a technique may have the advantage that the complexity and scope of each individual ML algorithm may be limited, particularly compared to a scenario where a single ML algorithm quantifies a plurality of aging mechanisms. As a result, it can be possible to train each individual ML algorithm especially precisely and thus to determine the aging value of the battery especially precisely overall.

In addition, it may be possible to use different types of ML algorithms to quantify different aging mechanisms. For example, a support vector machine (SVM) could be used to quantify a first aging mechanism and an artificial neural network used to quantify a second aging mechanism. Such techniques are based on the knowledge that often—for example depending on the type of input variable—different ML algorithms can work especially efficiently and precisely.

Next, some specific examples are described in connection with the one or more derived state quantities which can be used as input values for the ML algorithm.

For example, it would be possible for the one or more derived state variables to contain an anode potential of at least one cell of the battery and/or a cathode potential of at least one cell of the battery and/or a ratio between the anode potential and the cathode potential.

For example, the anode potential is indicative of the aging mechanism of lithium deposition (lithium plating). In this case, the upstream algorithm could be implemented, for example, by a simulation according to Ecker, Madeleine. Lithium Plating in Lithium-Ion Batteries: An Experimental and Simulation Approach. Shaker Verlag, 2016, Chapter 5.2. The anode potential for lithium-ion batteries correlates with lithium deposition. Lithium deposition typically causes sudden or non-linear aging, i.e. a drop in the capacity of the battery as a function of charge cycles or operating time. Such a non-linear aging often cannot be detected, or only to a limited extent, by an ML algorithm which only obtains the directly observable state variables as input values. In such a case, a large amount of training data would typically have to be taken into account. The aging value can therefore be determined especially precisely using the techniques described.

The ratio between the anode potential and the cathode potential is also referred to as electrode balancing. This ratio has been found to be indicative of battery aging. For example, if the anode overhang decreases due to aging, the potential level of the electrodes shifts. This results in a different electrode balancing.

In a further example, the one or more derived state variables can comprise a differential voltage spectrum and/or a differential capacity spectrum of a discharge curve—for example in the case of small current flows—of at least one cell of the battery. Such a technique is also often referred to as differential voltage analysis (DVA).

The DVA corresponds to an analysis of the voltage characteristic of a battery cell during discharge with a constant current flow. Alternatively or additionally, however, charging with a constant flow of charging current could also be considered. For example, the change in voltage for varying states of charge could be plotted as a function of the state of charge. The change in state of charge for varying voltages could also be plotted against the state of charge. See, for example, Keil, Peter. Aging of lithium-ion batteries in electric vehicles. Diss. Technical University of Munich, 2017: FIG. 16. Using a DVA, it is possible to determine the loss of cathode material— for example lithium—and the loss of anode material as one or more derived state variables and thus as input values for the at least one ML algorithm (loss of Li inventory, LLI; and loss of anode material, LAM). For example, it would be possible within the framework of the DVA to determine the position and/or height of local maxima of the respective characteristic curve, as described above, and to use them as an input value for the at least one ML algorithm. A correlated increase in LLI and LAM may correlate with the lithium plating aging mechanism.

Furthermore, the one or more derived state variables could comprise mechanical stress of at least one cell of the battery. Algorithms are known, for example, which describe the expansion of the battery cells as a function of the temperature, the state of charge, and/or the charge/discharge rate. See, for example, Oh, Ki-Yong and Bogdan I. Epureanu. “A novel thermal swelling model for a rechargeable lithium-ion battery cell.” Journal of Power Sources 303 (2016): 86-96 and Oh, Ki-Yong, et al. “A novel phenomenological multiphysics model of Li-ion battery cells.” Journal of Power Sources 326 (2016): 447-458. Mechanical stress, as a further derived state variable, can also be caused by various aging mechanisms, in particular thickening of the battery due to thermal swelling. Thus, the increase in thickness due to aging can arise from SEI growth and/or lithium deposition and irreversible electrode work. By determining the mechanical stress, it is therefore possible to quantify multiple aging mechanisms.

The one or more derived state variables could also comprise open circuit voltage of at least one cell of the battery. The upstream algorithm could be implemented analytically, for example, and the measurement data could be obtained in an event-based manner, for example if a certain pause phase/rest time for the battery has been reached. Then the voltage is indicative of an open circuit voltage with no load.

In another example, the one or more derived state variables can comprise a load spectrum that is determined by an upstream algorithm based on the measurement data (in other examples, however, it would also be possible for the load spectrum to be obtained in the form of the measurement data; i.e., the load spectrum could be determined locally at the batteries, which limits the amount of transmission data required).

It can be seen from the above description that different derived state variables can be flexibly determined by using one or more upstream algorithms. This can be used to obtain especially comprehensive information regarding the state of the battery. Then, as part of the second stage, the aging value of the battery can be determined especially precisely by the at least one ML algorithm.

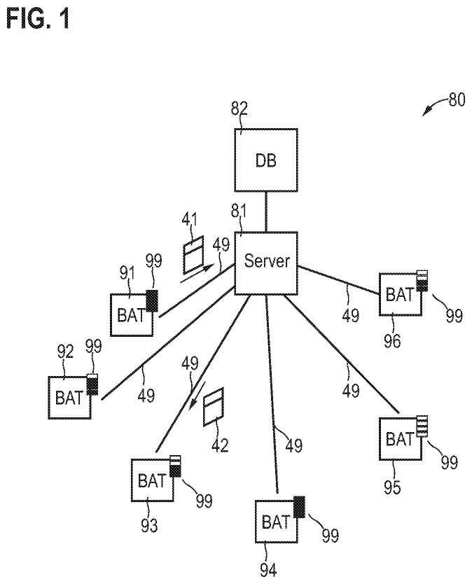

FIG. 1 illustrates aspects related to a system 80. The system 80 comprises a server 81 that is connected to a database 82. In addition, the system 80 comprises communication links 49 between the server 81 and each of a plurality of batteries 91-96. The communication links 49 could be implemented over a cellular network, for example. For example, batteries 91-96 can form an ensemble, i.e. all be of the same type.

FIG. 1 illustrates, by way of example, that the batteries 91-96 can send measurement data 41 to the server 81 via the communication links 49. For example, it would be possible for the measurement data 41 to be indicative of one or more state variables of the respective battery 91-96, e.g. state of charge, current flow, voltage, etc.

FIG. 1 also illustrates, by way of example, that the server 81 can transmit control data 42 to the batteries 91-96 via the communication links 49. For example, it would be possible for the control data 42 to indicate one or more operating limits for the future operation of the respective battery 91-96. For example, the control data could indicate one or more control parameters for thermal management of the respective battery 91-96 and/or charging management of the respective battery 91-96. By using the control data 42, the server 81 can thus influence or control the operation of the batteries 91-96. For example, this could be based on an aging value that is determined by the server 81 for the respective battery.

FIG. 1 also schematically illustrates a respective aging value 99 for each of the batteries 91-96 (for example, the battery 95 has aged comparatively significantly and the batteries 91, 94 have not yet aged especially much). Techniques for determining the aging value 99 are described below.

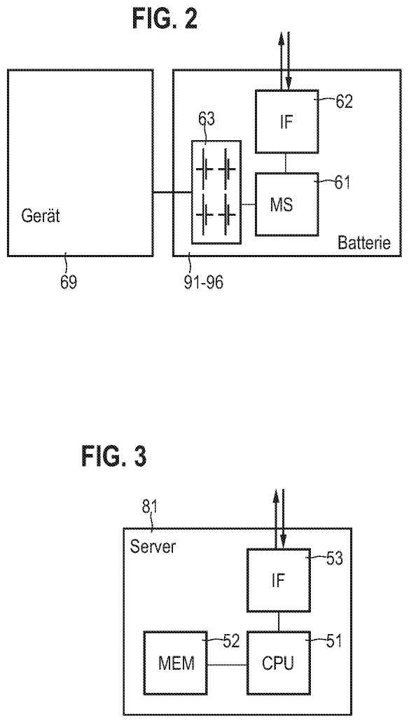

FIG. 2 illustrates aspects related to the batteries 91-96. The batteries 91-96 are coupled to a respective device 69. This device—for example an electric motor—is powered by electrical energy from the respective battery 91-96.

The batteries 91-96 comprise or are associated with one or more management systems 61, e.g. a BMS or other control logic such as an on-board unit in the case of a vehicle. The management system 61 can be implemented by software on a CPU, for example. Alternatively or additionally, for example, an application-specific integrated circuit (ASIC) or a field programmable gate array (FPGA) can be used. The batteries 91-96 could communicate with the management system 61 via a bus system, for example. The batteries 91-96 also comprise a communication interface 62. The management system 61 can establish a communication link 49 with the server 81 via the communication interface 62.

While FIG. 2 shows the management system 61 separately from the batteries 91-96, in other examples it would also be possible for the management system 61 to be part of the batteries 91-96.

In addition, the batteries 91-96 comprise one or more battery packs 63. Each battery pack 63 typically comprises several battery cells connected in parallel and/or in series. Electrical energy can be stored there.

Typically, the management system 61 can rely on one or more sensors in the one or more battery packs 63. For example, the sensors can measure state variables of the respective battery, such as the current flow and/or the voltage in at least some of the battery cells. Alternatively or additionally, the sensors can also measure other state variables in connection with at least some of the battery cells, for example temperature, volume, pressure, etc. The management system 61 can then be set up to send one or more such measurement values from sensors to the server 81 in the form of measurement data 41.

The measurement values can be pre-processed to a lesser or greater extent by the management system 61 before they are transmitted in the form of the measurement data 41. For example, compression would be conceivable, for example in the form of a load spectrum. Measured values could also be filtered, for example event-based.

FIG. 3 illustrates aspects related to the server 81. The server 81 comprises a processor 51 and a memory 52. The memory 52 may comprise a volatile memory element and/or a non-volatile memory element. The server 81 also comprises a communication interface 53. The processor 51 can establish a communication link 49 with each of the batteries 91-96 and the database 82 via the communication interface 53.

For example, program code may be stored in the memory 52 and loaded by the processor 51. The processor 51 can then execute the program code. Execution of the program code causes the processor 51 to perform one or more of the following processes, as they are described in detail herein in connection with the various examples: characterizing batteries 91-96; determining an aging value 99 for the batteries 91-96; applying an upstream algorithm to determine one or more derived state variables, e.g. with one or more simulations, such as an electrical simulation or a thermal simulation of the batteries 91-96; training and/or applying an ML algorithm to determine the aging value based on a result of an upstream algorithm; transmitting control data to the batteries 91-96, for example to set boundary operating conditions; storing a result of a characterization or of an aging value of a corresponding battery 91-96 in a database 82; etc.

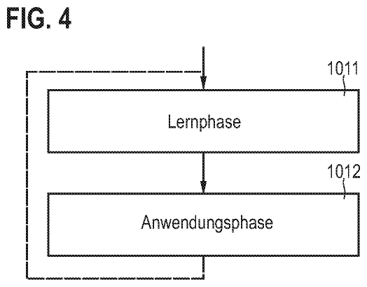

FIG. 4 is a flowchart of an exemplary method. The method is typically performed by a server. The method is used to characterize a battery on the server side. For example, it would be possible for the method according to FIG. 4 to be executed by the processor 51 of the server 81 based on program code from the memory 52 (cf. FIG. 3).

First, in box 1011, a learning phase is performed for an ML algorithm. During the learning phase, the ML algorithm is trained. This means that parameter values or weights are set for the ML algorithm based on training data and a priori knowledge related to the training data. For example, back propagation techniques could be used in the context of an artificial neural network.

As a general rule, different training data can be taken into account as part of the learning phase. As a general rule, there are different variants regarding the implementation of the training data. In one variant, the training data could be obtained, for example, from laboratory measurements in which a battery is examined in the laboratory. For example, invasive probing techniques could be used, in which additional detectors and sensors are placed in the battery which are not present in the field devices of the respective battery. In a further variant, however, the training data could also be obtained by measurements on field devices. For example, the training data could comprise reference data from an ensemble of reference batteries (cf. FIG. 1: batteries 91-96). This reference data could comprise, for example, measured values for one or more state variables of these reference batteries. The reference data can also comprise a priori knowledge of a respectively associated aging value for the batteries. For example, complete or almost complete discharge could occur for some reference batteries in the respective driving cycle, wherein this can then be used to determine the total capacity as an aging value. A further option would be the use of a Kalman filter to estimate the state such as it is described, for example, in Plett, Gregory L. “Extended Kalman filtering for battery management systems of LiPB-based HEV battery packs: Part 2. Modeling and identification.” Journal of power sources 134.2 (2004): 262-276. Then the ML algorithm can be trained, in box 1011, based on such reference data. Using such techniques, the learning phase can in particular be repeatedly executed interleaved with an application phase—cf. box 1012—in which the trained ML algorithm is used to determine the aging value (this is represented by the dashed line in FIG. 4). This means that, based on measurements in field devices, the accuracy of the characterization can be continuously improved.

For example, the reference data could have expanded information content compared to the measurement data that is obtained in normal ongoing operation. This concerns, for example, the possibility of obtaining or deriving the a priori knowledge of the aging value from the reference data. For example, it would be conceivable that a complete discharging/charging process is monitored, i.e. corresponding current-voltage time series are recorded. Then the entire charge that has flowed could be indicative of the capacity of the battery and thus the aging value. A corresponding amount of data can be especially large. It can therefore sometimes be helpful to request the reference data selectively. This means that the method involves requesting the reference data by means of a control command sent to management systems associated with the reference batteries. For example, it would be possible to first buffer such data in an internal memory of the management systems and then transmit it to the server via a broadband connection when required, for example when a loading process is initiated in a broadband connection environment.

In box 1012, the application phase occurs. In this case, measurement data of a battery are received—for example one of the batteries 91-96 from FIG. 1—which is indicative of one or more state variables.

For example, the measurement data could indicate the one or more state variables as a load spectrum. This could result in a significant reduction in the data required compared to the reference data from box 1011, for example. This makes it possible to repeatedly characterize the battery while the battery is in operation without the amount of data to be transmitted becoming excessive.

In some examples, it would be possible in this context for the measurement data to be transmitted incrementally (incremental update). This means that, for example, changes in the load spectrum are indicated as time progresses, in each case referenced to previously transmitted measurement data. A further reduction in the bandwidth can take place in this way. By buffering the measurement data on the server, the entire information content can still be reconstructed.

It would be possible for the application phase to be activated selectively, namely depending on a training level of the ML algorithm. The ML algorithm can be activated selectively depending on the training level. In a scenario in which reference data is first collected as training data for an ensemble of batteries in field operation, this could prevent comparatively inaccurate results from being achieved by an insufficiently trained ML algorithm (so-called cold start problem). Instead of using the ML algorithm to characterize the battery in such a cold start phase, an alternative algorithm, for example an empirically parameterized characterization algorithm, can be used to determine the aging value.

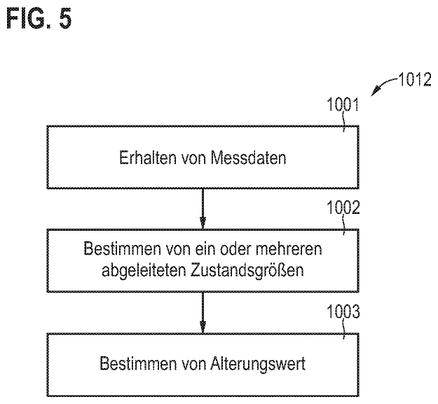

FIG. 5 is a flowchart of an exemplary method. The method is performed by a server. The method is used to characterize a battery on the server side. For example, it would be possible for the method according to FIG. 5 to be executed by the processor 51 of the server 81 based on program code from the memory 52 (cf. FIG. 3). The method according to FIG. 5 can be executed, for example, within box 1012 according to the method from FIG. 4. This means that the method of FIG. 5 indicates an application phase of an ML algorithm.

In this case, measurement data are obtained in box 1001 which are indicative of one or more state variables of a battery. The one or more state variables can comprise, for example, the current flow in one or more cells of the battery, and/or a voltage across one or more cells of the battery, and/or a temperature of one or more cells of the battery, and/or a depth of discharge of the battery, and/or a duration of pause phases during which no significant charge is drawn off or fed in, and/or a state of charge (SOC) of the battery.

Then, in box 1002, one or more derived state variables are determined, wherein one or more upstream algorithms are used for this purpose. The one or more upstream algorithms could comprise, for example, analytical or numerical algorithm modules. For example, the one or more upstream algorithms could comprise a simulation of, for example, a temperature behavior or an electrical characteristic of the battery. It would be possible for an analytical algorithm to be parameterized by empirical measurements.

As a result of box 1002, one or more derived state variables are then obtained.

In box 1003, an aging value of the battery—i.e., for example a value indicative of capacity and/or impedance—is then determined using one or more ML algorithms. The one or more ML algorithms obtain the one or more derived state variables from box 1002 as input values.

Depending on the aging value, it would then be possible for the respective battery to be controlled accordingly, the battery being set, for example, in the boundary operating conditions.

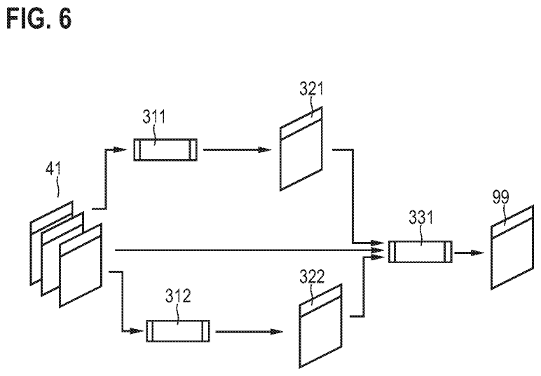

FIG. 6 illustrates aspects related to a two-stage approach for determining an aging value 99. FIG. 6 is a data flowchart for a corresponding determination. For example, the data processing according to FIG. 6 could be executed in connection with the method from FIG. 5.

A first stage involves applying two upstream algorithms 311-312; and a second stage involves applying an ML algorithm 331. The ML algorithm 331 provides the aging value 99 as a result. Therefore, the first stage can correlate with box 1002 from the method of FIG. 5, and the second stage can correlate with box 1003 from the method of FIG. 5.

In general, however, it would also be possible for multiple ML algorithms to be used in the context of the second stage, each providing a contribution to the final aging value 99 as a result. The aging value 99 can then be obtained by combining the results of the various ML algorithms, wherein the various results correlate with different aging mechanisms, for example.

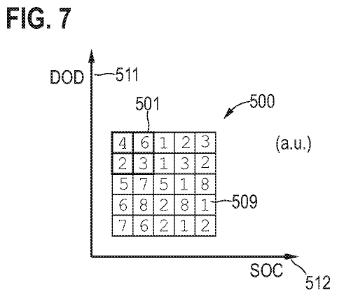

In FIG. 6, measurement data 41 are used as an input for the two-stage process. For example, measurement data can be obtained from one of the batteries 91-96 via the communication link 49. The measurement data 41 could be present as a load spectrum, for example. An exemplary load spectrum 500 is shown in FIG. 7. The state variables of depth of discharge 511 and state of charge 512 in the load spectrum 500 are correlated with one another. The corresponding values 509 indicate the—typically relatively defined—frequency of operation of the respective battery 91-96 for the respective state variables 511-512 (with a relatively defined frequency, the assumption is that the load profile of the battery and thus the load spectrum for a specific purpose of the battery remains constant, i.e. shows no change over time). However, a time resolution is not provided by measurement data which is present in the form of the load spectrum 500. Such techniques are based on the knowledge that the dynamics of the corresponding state variables 501, 502 have a comparatively small influence on aging—in contrast to the relative frequency of occurrence, for example in specific areas 501 of the load spectrum 500 with especially severe aging. It may therefore be sufficient for the measurement data to not indicate the state variables 511, 512 in a time-resolved manner, but rather in the form of a load spectrum 500. In addition, the amount of data in the measurement data 41 is thereby compressed.

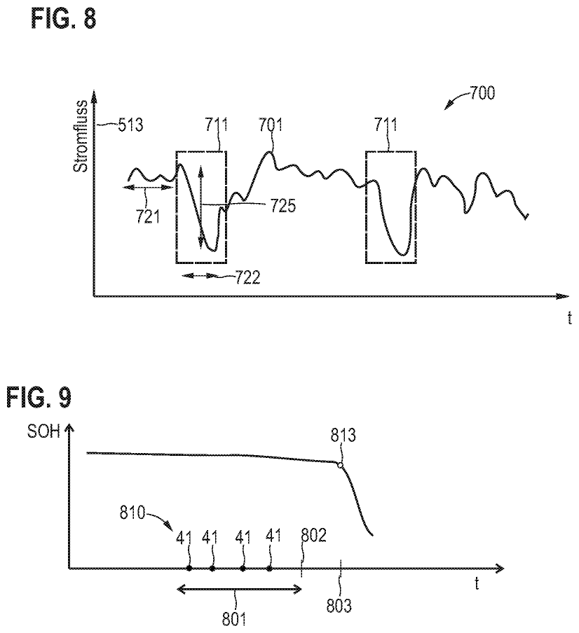

In a further example, it would be conceivable for the measurement data 41 to indicate the one or more state variables of the battery at least partially in an event-based manner. A corresponding example is shown in FIG. 8. FIG. 8 shows an event-based representation 700 of the state variable of electrical current flow 513. FIG. 8 shows that, for specific events 711 (indicated by the dashed frame), a corresponding parameter 725 of the events 711 could be transmitted to the server 81 in the form of the measurement data 41. In the example according to FIG. 8, the event 711 is characterized by a drop in current flow 513 over a period of time 722 following a period 721 of relatively constant current flow. The drop hub 725 could, for example, be transmitted to the server 81 in the form of the measurement data 41 and then used as part of one of the upstream algorithms 311-312 to determine a corresponding derived state variable 321-322. However, this is only an example and other implementations of event-based measurement data are conceivable.

Referring again to FIG. 6: An example is shown in which two upstream algorithms 311-312 are used to determine state variables 321-322 derived on the basis of the measurement data 41. As a general rule, it would be possible for just one upstream algorithm to be used or for more than two upstream algorithms to be used. If more than one upstream algorithm is used, then different upstream algorithms can rely, at least partially, on different parts of the measurement data 41 as an input variable. For example, it would be conceivable that different parts of the measurement data 41 associated with other state variables are supplied to different upstream algorithms 311, 312.

For example, it would be conceivable for measurement data 41 that are indicative of an anode potential of a cell of the battery to be supplied to the upstream algorithm 311 and, based thereon, the derived state variable 321 that correlates with the degree of lithium deposition to be determined. It would be conceivable that such a part of the measurement data 41 is supplied to the further upstream algorithm 312 as an input variable, which upstream algorithm corresponds to a differential voltage spectrum or a differential capacity spectrum of a discharge curve of a cell of the battery. Then, based on this, the derived state variable 322 which correlates with the loss of lithium ions or anode material could be determined. These are just two examples, and it is conceivable that other upstream algorithms are used or other derived state variables are determined. For example, it could be possible that a mechanical stress of cells of the battery is determined. The open circuit voltage of the at least one cell of the battery could also be determined.

In the example of FIG. 6, the derived state variables 321-322 are then supplied to the (single) ML algorithm 331 as input variables. In general, however, it would also be possible for several ML algorithms to be used, for example different ML algorithms depending on the derived state variable 321-322.

As in the example of FIG. 6, it can also be possible that, in addition to the derived state variables 391-322, the state variables from the measurement data 41 are also supplied to the one or more ML algorithms 331 as input variables.

In particular, it would be conceivable in various examples for a load spectrum to be supplied to the one or more ML algorithms 331 as an input. Using the load spectrum, it may be possible to characterize the load profile of the battery over the measurement period. In this way, the aging value can be predicted for a future point in time. This is based on the knowledge that, when the battery is subjected to a greater load, aging will progress more rapidly than when the battery is subjected to a weaker load. It may therefore be possible in the various examples described herein to use a feedforward ANN that retains one or more load spectra as an input value and provides the aging value at a forecast time as an output value (assuming that the historical load profile also corresponds to the future load profile, i.e. the relative part of operation with certain stress factors is constant over time).

Other state variables that can be derived directly from the measurement data using simple operations (e.g., summation, histogramming, min or max operation, etc.) are: average charging time, maximum temperature, minimum depth of discharge, etc.

FIG. 9 illustrates aspects related to the measurement data 41. In the example in FIG. 9, a time series 810 of measurement data 41 is obtained. The measurement data 41 of the time series 810 have measurement times that are distributed over a measurement time interval 801. The measurement time interval 801 extends starting from the actual point in time 802 into the past.

For example, the measurement data 41 of the time series 810 could respectively indicate values for the current or the voltage or the temperature at the respective measurement time in the measurement time interval 801. A load spectrum could then be formed therefrom, or certain events could be recognized. However, it would also be possible for the measurement data 41 of the time series 810 to indicate a load spectrum at the respective measurement time in the measurement time interval 801, wherein the respective load spectrum is determined on the basis of values observed between the respective measurement time and the previous measurement time, for example. This therefore means that the change in the load could be described by the multiple load spectra.

As a general rule, it is optional that the measurement data 41 provide a corresponding time series 810. It would also be conceivable, for example, for the measurement data 41 to only indicate values for one or more state variables at the actual point in time 802. For example, the measurement data 41 could comprise a single load spectrum, which is determined on the basis of values observed over the entire measurement time interval 801 up to the current actual point in time.

FIG. 9 also illustrates aspects related to the prediction of the aging value 813. In the example of FIG. 9, the aging value 813 is predicted for a point in time 803 in the future.

Such a prediction of the aging value at a future point in time can be based on the corresponding time series 810, for example. There are various ways to do this, which are summarized in Table 1:

TABLE 1
Variants for predicting the aging value

| | | Output of upstream algorithm, input of ML |
|---|---|---|
| Example | Input of upstream algorithm | algorithm |
| A | Time series of state variables in | Time series of derived state variables in |
| | measurement time interval | measurement time interval |
| B | Time series of state variables in | Derived state variables at a future point in time |
| | measurement time interval | |
| C | State variable as a load spectrum | Derived state variables at a future point in time |
| | in measurement time interval | |
| D | Time series of state variables in | Derived state variables, particularly load |
| | measurement time interval | spectrum |
| E | State variable as a load spectrum | Derived state variables as a load spectrum in |
| | in the measurement time interval | measurement time interval |

For example, in Example B and Example C, it may not be necessary to use an ML algorithm that receives a time series of data as an input. A feedforward ANN could be used, for example. In example A, a recurrent ANN could be used.

In example C, it may not be necessary to monitor the one or more state variables of the battery in a time-resolved manner. Rather, the development of the one or more derived state variables can be inferred by the upstream algorithm by taking into account the load profile of the battery as a load spectrum. The load spectrum can describe, for example, how often the battery is discharged/charged with a certain depth of discharge and/or discharge rate (e.g. in a critical temperature range), what the charging rate is, how quickly the battery is discharged, what the operating temperature is during charging or discharging of the battery, etc. Such stress factors can then be used as a load profile to deduce how the one or more derived state variables of the battery will behave in the future. In example C, the upstream algorithm can be used for this.

In example D, it would be possible, for example, for a time series of directly observed state variables—for example current flow, voltage, temperature—to be obtained in the form of measurement data 41 in the measurement time interval. One or more derived state variables, which correlate with one or more aging mechanisms of the battery, can then be determined using the upstream algorithm.

A load spectrum can also be determined which quantifies stress factors of the battery as a load profile on the basis of the time series of state variables. Such derived state variables can then be used as input values of the ML algorithm. In this example, the ML algorithm can be embodied in particular as a feedforward ANN. A time series does not have to be considered. A prediction of the aging value can be achieved by suitably training the ML algorithm, namely taking into account the—for example relatively defined—load spectra. The load spectrum can be used to characterize the load on the battery so that greater or lesser aging can be predicted in the future.

In example E, a further load spectrum for one or more derived state variables can be determined from a load spectrum for one or more state variables.

In the various examples from Table 1—as described above, for example in connection with FIG. 6—other state variables can also be used as an input into the ML algorithm, i.e. the input into the ML algorithm is not limited to the output of the upstream algorithm. Particularly in connection with the prediction of the aging value at the future point in time, it may be desirable in this context to consider statistics of a state variable in the measurement time interval as an input into the ML algorithm (in general, a state variable can be taken into account that is also evaluated by the upstream algorithm, or another state variable). A statistic of the state variable of measurement time interval can therefore describe an evaluation of the behavior of the state variable—such as current or voltage or temperature, etc.—in the measurement time interval. For example, the statistic could describe one or more of the following statistical variables: maximum of the state variable, such as maximum temperature in the measurement time interval; minimum of the state variable, such as the minimum temperature in the measurement time interval; mean value of the state variable, such as mean temperature in the measurement time interval; dispersion of the state variable, i.e. variance of the temperature in the measurement time interval; etc. As a general rule, the statistic of the state variable could be determined based on the time series of the state variable or obtained directly from an appropriate controller of the respective battery.

Obviously, the features of the embodiments and aspects of the invention described above can be combined with one another. In particular, the features can be used not only in the combinations described, but also in other combinations or used in isolation, without departing from the field of the invention.

1. A computer-implemented method for determining an aging value of a rechargeable battery, wherein the method comprises:
obtaining measurement data for one or more state variables of the battery,
determining one or more derived state variables of the battery using an upstream algorithm, wherein input values of the upstream algorithm comprise the one or more state variables, and
determining the aging value using at least one machine-learned algorithm, wherein input values of the at least one machine-learned algorithm, comprise the one or more derived state variables of the battery.

2. The method according to claim 1,
wherein the one or more derived state variables comprise at least one of an anode potential of at least one cell of the battery, a cathode potential of the at least one cell of the battery as well as a ratio between the anode potential and the cathode potential.

3. The method according to claim 1,
wherein the one or more derived state variables comprise at least one of a differential voltage spectrum or a differential capacity spectrum of a discharge curve of at least one cell of the battery.

4. The method according to claim 1,
wherein the one or more derived state variables comprise at least one of a loss of cathode material or a loss of anode material.

5. The method according to claim 1,
wherein the one or more derived state variables comprise mechanical stress of at least one cell of the battery.

6. The method according to claim 1,
wherein the one or more derived state variables comprise an open circuit voltage of at least one cell of the battery.

7. The method according to claim 1,
wherein the one or more derived state variables comprise a load profile of the battery.

8. The method according to claim 1,
wherein the input values of the at least one machine-learned algorithm further comprise a statistic of the one or more state variables of the battery or one or more further state variables the battery in a measurement time interval.

9. The method according to claim 1,
wherein input values of the machine-learned algorithm further comprise the one or more state variables of the battery.

10. The method according to claim 1,
wherein the at least one machine-learned algorithm quantifies multiple aging mechanisms,
wherein the aging value determined based on a combination of values for the multiple aging mechanisms.

11. The method according to claim 10,
wherein the at least one machine-learned algorithm comprises multiple machine-learned algorithms assigned to different aging mechanisms.

12. The method according to claim 1,
wherein the measurement data are received, on a server via a communication link, from a management system of the battery,
wherein the measurement data are within a measurement time interval which is determined using a sliding window method.

13. The method according to claim 1, which further comprises:
receiving reference data from an ensemble of reference batteries on a server and
training the at least one machine-learned algorithm based on the reference data.

14. The method according to claim 1,
wherein the measurement data indicate the one or more state variables as a load spectrum and/or as event-based.

15. The method according to claim 1,
wherein the one or more state variables comprise: an electrical current flow in one or more cells of the battery, an electrical voltage across one or more cells of the battery, a temperature of one or more cells of the battery, a depth of discharge of the battery, a duration of pause phases, or a state of charge of the battery.

16. The method according to claim 1,
wherein the measurement data comprise a time series for the one or more state variables of the battery,
wherein a time series of the one or more derived state variables of the battery is determined using the upstream algorithm,
wherein the input values of the at least one machine-learned algorithm comprise the time series of the one or more derived state variables.
